(19) United States
(12) Patent Application Publication
(10) Pub. No.: US 2026/0135548 A1
(43) Pub. Date: May 14, 2026

(54) COMPARISON CIRCUIT PERFORMING COMPARATOR OFFSET CALIBRATION AND METHOD OF OPERATING THE SAME

(71) Applicant: Samsung Electronics Co., Ltd., Suwon-si (KR)

(72) Inventors: Hyeongjin Yoo, Suwon-si (KR); Junsub Yoon, Suwon-si (KR); Osung Kwon, Suwon-si (KR)

(21) Appl. No.: 19/190,185

(22) Filed: Apr. 25, 2025

(30) Foreign Application Priority Data
Nov. 8, 2024 (KR) 10-2024-0157958

(51) Int. Cl. H03K 5/26

(52) U.S. Cl. CPC H03K 5/26

(57) ABSTRACT

A comparison circuit includes a comparator and a multiplexer. The comparator includes at least one transistor and generates a first output signal based on a first input signal, a second input signal, and an operating clock signal. The multiplexer, in a normal mode, outputs a first clock signal as the operating clock signal based on a control signal, and in an offset calibration mode, outputs a second clock signal different from the first clock signal as the operating clock signal based on the control signal. In the offset calibration mode, the comparison circuit is configured to perform an offset calibration operation by degrading the at least one transistor based on the first and second input signals having the same voltage level and the operating clock signal.

### CROSS-REFERENCE TO RELATED APPLICATION(S)

This application claims priority under 35 USC § 119 to Korean Patent Application No. 10-2024-0157958 filed on Nov. 8, 2024 in the Korean Intellectual Property Office (KIPO), the disclosure of which is herein incorporated by reference in its entirety.

### BACKGROUND

### 1. Technical Field

Example embodiments relate generally to semiconductor integrated circuits, and more particularly to comparison circuits performing comparator offset calibration and methods of operating the comparison circuits.

### 2. Description of the Related Art

A comparator which generates an output signal indicating a comparison result by comparing input signals may be used for various applications. For example, an analog-to-digital converter (ADC) for converting an analog signal into a digital signal may include a plurality of comparators and generate the digital signal by encoding output signals from the plurality of comparators. For example, a switching regulator may include a comparator for comparing a feedback signal to a reference signal.

The performance and efficiency of the applications may depend on characteristics of a comparator, e.g., power consumption, operating speed, noise properties, area, accuracy, and the like, and some of the characteristics of the comparator may be in a trade-off relationship. Accordingly, it may be difficult to implement a comparator with better characteristics in all aspect.

### SUMMARY

At least one example embodiment of the present disclosure provides a comparison circuit capable of efficiently performing a comparator offset calibration.

At least one example embodiment of the present disclosure provides a method of operating the comparison circuit.

According to example embodiments, a comparison circuit includes a comparator and a multiplexer. The comparator includes at least one transistor and is configured to generate a first output signal based on a first input signal, a second input signal, and an operating clock signal. The multiplexer is configured, in a normal mode, to output a first clock signal as the operating clock signal based on a control signal, and in an offset calibration mode, to output a second clock signal different from the first clock signal as the operating clock signal based on the control signal. In the offset calibration mode, the comparison circuit is configured to perform an offset calibration operation by degrading the at least one transistor based on the first and second input signals having the same voltage level, and the operating clock signal.

According to example embodiments, a method of operating a comparison circuit including at least one transistor includes determining whether an operation mode of the comparison circuit is an offset calibration mode or a normal mode, when the operation mode of the comparison circuit is the offset calibration mode, performing an offset calibration operation by degrading the at least one transistor based on first and second input signals having the same voltage level and an operating clock signal, and when the operation mode of the comparison circuit is the normal mode, performing a normal operation based on the first and second input signals having different voltage levels the operating clock signal.

According to example embodiments, a comparison circuit includes a comparator and a multiplexer. The comparator includes at least one transistor and is configured to generate a first output signal based on a first input signal, a second input signal, and an operating clock signal. The multiplexer is configured, in a normal mode, to output a first clock signal as the operating clock signal based on a control signal, and in an offset calibration mode, to output a second clock signal different from the first clock signal as the operating clock signal based on the control signal. The comparator includes a first p-channel metal-oxide semiconductor (PMOS) transistor, a second PMOS transistor, a third PMOS transistor, a fourth PMOS transistor, a first n-channel metal-oxide semiconductor (NMOS) transistor, a second NMOS transistor, a third NMOS transistor, a fourth NMOS transistor, and a fifth NMOS transistor. The first PMOS transistor and the second PMOS transistor are connected in parallel between a terminal to which a power supply voltage is applied and a terminal from which the first output signal is output. The first PMOS transistor includes a gate terminal connected to a terminal to which the operating clock signal is input. The second PMOS transistor includes a gate terminal connected to a terminal from which a second output signal is output. The third PMOS transistor and the fourth PMOS transistor are connected in parallel between the terminal to which the power supply voltage is applied and the terminal from which the second output signal is output. The third PMOS transistor includes a gate terminal connected to the terminal from which the first output signal is output. The fourth PMOS transistor includes a gate terminal connected to the terminal to which the operating clock signal is input. The first NMOS transistor and the second NMOS transistor are connected in series between the terminal from which the second output signal is output and a first node. The first NMOS transistor includes a gate terminal connected to the terminal from which the first output signal is output. The second NMOS transistor includes a gate terminal connected to a terminal to which the first input signal is input. The third NMOS transistor and the fourth NMOS transistor are connected in series between the terminal from which the first output signal is output and the first node. The third NMOS transistor includes a gate terminal connected to the terminal from which the second output signal is output. The fourth NMOS transistor includes a gate terminal connected to a terminal to which the second input signal is input. The fifth NMOS transistor is connected between the first node and a ground node, and includes a gate terminal connected to the terminal to which the operating clock signal is input.

In the comparison circuit and the method of operating the comparison circuit according to example embodiments, comparator offset calibration may be performed by degrading at least one transistor in the comparator included in the comparison circuit. For example, the comparator offset calibration may be performed by degrading the transistor in the comparator without additional circuit configuration. Therefore, the comparator offset calibration may be performed efficiently without increasing the load of the circuit.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a comparison circuit according to example embodiments.

FIG. 2 is a block diagram illustrating a comparison circuit according to example embodiments.

FIG. 3 is a circuit diagram illustrating an example of a comparator included in a comparison circuit of FIG. 1 according to example embodiments.

FIGS. 4A and 4B are circuit diagrams for describing an operation of a comparator of FIG. 3 according to example embodiments.

FIG. 5A is a timing diagram for describing an operation of a comparator of FIG. 3 in a normal mode according to example embodiments.

FIG. 5B is a timing diagram for describing an operation of a comparator of FIG. 4A in an offset calibration mode according to example embodiments.

FIG. 5C is a timing diagram for describing an operation of a comparator of FIG. 4B in an offset calibration mode according to example embodiments.

FIG. 6 is a diagram illustrating a simulation result of a comparison circuit according to example embodiments.

FIG. 7 is a circuit diagram illustrating an example of a comparator included in a comparison circuit of FIG. 1 according to example embodiments.

FIGS. 8A and 8B are circuit diagrams for describing an operation of a comparator of FIG. 7 according to example embodiments.

FIG. 9 is a flowchart illustrating a method of operating a comparison circuit according to example embodiments.

FIG. 10 is a flowchart illustrating an example of performing a normal operation in a method of operating a comparison circuit according to example embodiments.

FIG. 11 is a flowchart illustrating an example of performing an offset calibration operation in a method of operating a comparison circuit according to example embodiments.

FIG. 12 is a flowchart illustrating a method of operating a comparison circuit according to example embodiments.

FIG. 13 is a block diagram illustrating a memory device according to example embodiments.

FIG. 14 is a block diagram illustrating an electronic system according to example embodiments.

FIG. 15 is a block diagram illustrating an integrated circuit according to example embodiments.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

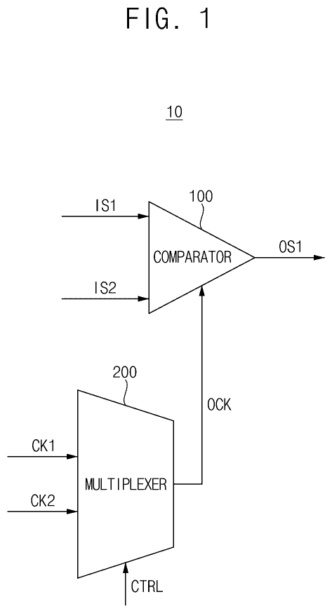

FIG. 1 is a block diagram illustrating a comparison circuit according to example embodiments.

Referring to FIG. 1, a comparison circuit 10 includes a comparator 100 and a multiplexer 200.

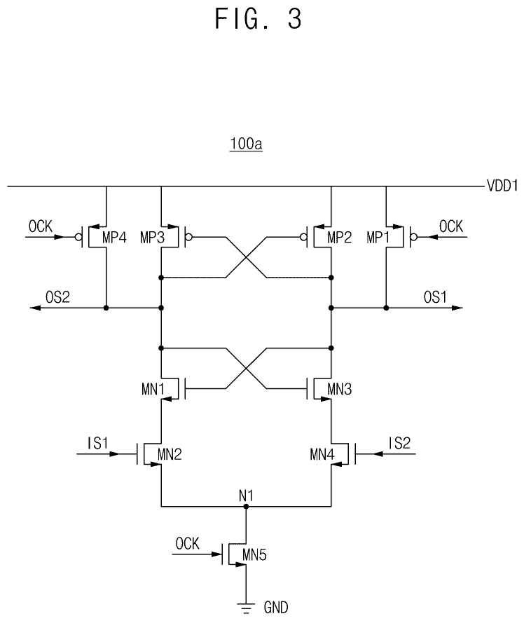

The comparator 100 includes at least one transistor and generates a first output signal OS1 based on a first input signal IS1, a second input signal IS2, and an operating clock signal OCK. For example, as will be described with reference to FIG. 3, etc., the comparator 100 may include a plurality of p-channel metal-oxide semiconductor (PMOS) transistors and a plurality of n-channel metal-oxide semiconductor (NMOS) transistors.

The comparator 100 may receive the first input signal IS1 and the second input signal IS2, and output the first output signal OS1 whose logic level varies depending on which of the first input signal IS1 and the second input signal IS2 has a higher level.

For example, when the first input signal IS1 has a level higher than the second input signal IS2, the comparator 100 may output the first output signal OS1 having a logic high level. For example, when the second input signal IS2 has a level higher than the first input signal IS1, the comparator 100 may output the first output signal OS1 having a logic low level.

However, example embodiments are not limited thereto, and when the first input signal IS1 has a level higher than the second input signal IS2, the comparator 100 may output the first output signal OS1 having a logic low level, and when the second input signal IS2 has a level higher than the first input signal IS1, the comparator 100 may output the first output signal OS1 having a logic high level.

The multiplexer 200 selects one of a first clock signal CK1 and a second clock signal CK2 based on a control signal CTRL and outputs the selected clock signal as the operating clock signal OCK.

The comparison circuit 10 according to example embodiments operates in a normal mode and an offset calibration mode. The normal mode represents an operation mode in which the comparison circuit 10 operates based on the first clock signal CK1 having a relatively high frequency and the first output signal OS1 is output depending on which of the first input signal IS1 and the second input signal IS2 has a higher level. For example, a normal operation may be performed in the normal mode. The offset calibration mode represents an operation mode in which the comparison circuit 10 operates based on the second clock signal CK2 having a relatively low frequency and the first input signal IS1 and the second input signal IS2 having the same voltage level are applied to perform an offset calibration operation by degrading at least one transistor.

For example, the frequency of the first clock signal CK1 may be a high frequency having a gigahertz (GHZ) unit, and the frequency of the second clock signal CK2 may be a low frequency having a kilohertz (KHZ) or megahertz (MHZ) unit.

For example, the offset calibration operation may be performed in the offset calibration mode during a manufacturing process of the comparison circuit 10, and the normal operation may be performed in the normal mode after the manufacturing process of the comparison circuit 10. However, example embodiments are not limited thereto, and the offset calibration operation may be performed after the manufacturing process of the comparison circuit 10.

The multiplexer 200 selects the first clock signal CK1 among the first clock signal CK1 and the second clock signal CK2 based on the control signal CTRL in the normal mode and outputs the first clock signal CK1 as the operating clock signal OCK. For example, the multiplexer 200 may determine that a current operation mode is the normal mode when the control signal CTRL has a logic low level and output the first clock signal CK1 as the operating clock signal OCK.

The multiplexer 200 selects the second clock signal CK2 among the first clock signal CK1 and the second clock signal CK2 based on the control signal CTRL in the offset calibration mode and outputs the second clock signal CK2 as the operating clock signal OCK. For example, the multiplexer 200 may determine that current mode is the offset calibration mode when the control signal CTRL have a logic high level and output the second clock signal CK2 as the operating clock signal OCK.

However, example embodiments are not limited thereto, and the multiplexer 200 may output the first clock signal CK1 as the operating clock signal OCK when the control signal CTRL have a logic high level, and may output the second clock signal CK2 as the operating clock signal OCK when the control signal CTRL have a logic low level in the offset calibration mode.

A comparator may be used when converting an analog signal to a digital signal. To operate the comparator in accordance with a clock signal having high speed, a plurality of comparators may be arranged in parallel. However, since the offsets that occur between the comparators are different from each other, a signal margin may be reduced.

Conventionally, an offset calibration circuit was added to calibrate the offsets that occurs between the comparators. When the offset calibration circuit is added, the load of the circuit may increase, which may degrade the characteristics of the circuit and may cause a hardware area problem.

In the comparison circuit 10 according to example embodiments, a comparator offset calibration may be performed by degrading the transistor in the comparator 100 without an additional offset calibration circuit. Therefore, the comparator offset calibration may be performed efficiently without increasing the load of the circuit.

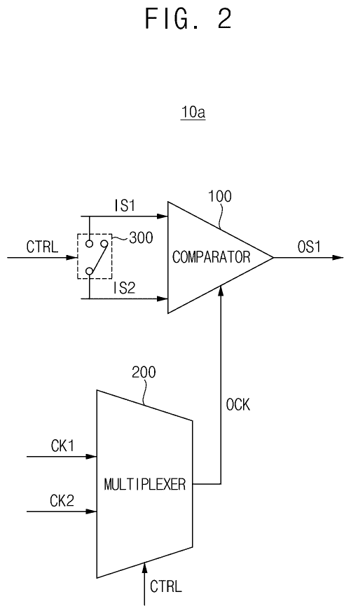

FIG. 2 is a block diagram illustrating a comparison circuit according to example embodiments.

Referring to FIG. 2, a comparison circuit 10a may further include a switch 300 compared to the comparison circuit 10 of FIG. 1. Hereinafter, the descriptions repeated with or overlapping with descriptions of FIG. 1 will be omitted in the interest of brevity.

In some example embodiments, the switch 300 may be connected between the first input signal IS1 and the second input signal IS2. For example, the switch 300 may be connected between an input terminal where the first input signal IS1 is received and an input terminal where the second input signal IS2 is received.

In some example embodiments, the switch 300 may be opened in the normal mode and closed in the offset calibration mode based on the control signal CTRL. For example, when the control signal CTRL have a logic high level, the switch 300 may be opened, and when the control signal CTRL have a logic low level, the switch 300 may be closed. However, example embodiments are not limited thereto, and when the control signal CTRL have a logic low level, the switch 300 may be opened, and when the control signal CTRL have a logic high level, the switch 300 may be closed.

In some example embodiments, the switch 300 may include a transistor including a gate terminal to which the control signal CTRL is applied. For example, when the transistor is turned off based on the control signal CTRL, the switch 300 may be opened, and when the transistor is turned on based on the control signal CTRL, the switch 300 may be closed.

In some example embodiments, when the switch 300 is opened based on the control signal CTRL, the first input signal IS1 and the second input signal IS2 may have different voltage levels. When the switch 300 is closed based on the control signal CTRL, the first input signal IS1 and the second input signal IS2 may have the same voltage level.

In some example embodiments, the switch 300 and the multiplexer 200 may receive the control signal CTRL simultaneously. For example, in the normal mode, when the control signal CTRL has a logic high level, the switch 300 may be opened, the first input signal IS1 and the second input signal IS2 having the different voltage levels may be received, and the multiplexer 200 may output the first clock signal CK1 as the operating clock signal OCK. For example, in the offset calibration mode, when the control signal CTRL have a logic low level, the switch 300 may be closed such that the first input signal IS1 and the second input signal IS2 have the same voltage level, and the multiplexer 200 may output the second clock signal CK2 as the operating clock signal OCK.

Although FIG. 2 illustrates an example where the switch 300 is connected between the input terminals of the comparator 100, example embodiments are not limited thereto. For example, the comparison circuit 10a may further include a buffer in front of the comparator 100 and the switch 300 may be connected between input terminals of the buffer.

Although FIG. 2 illustrates a case where the first input signal IS1 and the second input signal IS2 are controlled by the switch 300, example embodiments are not limited thereto, and the first input signal IS1 and the second input signal IS2 may be controlled by a voltage source without the switch 300.

In example embodiments, the offset calibration operation may be performed in the offset calibration mode during a manufacturing process of the comparison circuit 10a, and the normal operation may be performed in the normal mode after the manufacturing process of the comparison circuit 10a. However, example embodiments are not limited thereto, and the offset calibration operation may be performed after the manufacturing process of the comparison circuit 10a.

FIG. 3 is a circuit diagram illustrating an example of a comparator included in a comparison circuit of FIG. 1 according to example embodiments.

Referring to FIG. 3, a comparator 100a may include a first PMOS transistor MP1, a second PMOS transistor MP2, a third PMOS transistor MP3, a fourth PMOS transistor MP4, a first NMOS transistor MN1, a second NMOS transistor MN2, a third NMOS transistor MN3, a fourth NMOS transistor MN4, and a fifth NMOS transistor MN5.

The first PMOS transistor MP1 may include a source terminal connected to a terminal to which a first power supply voltage VDD1 is applied, a drain terminal connected to a terminal from which the first output signal OS1 is output, and a gate terminal connected to a terminal to which the operating clock signal OCK is input.

The second PMOS transistor MP2 may include a source terminal connected to the terminal to which the first power voltage VDD1 is applied, a drain terminal connected to the terminal from which the first output signal OS1 is output, and a gate terminal connected to a terminal from which a second output signal OS2 is output.

The third PMOS transistor MP3 may include a source terminal connected to the terminal to which the first power voltage VDD1 is applied, a drain terminal connected to the terminal from which the second output signal OS2 is output, and a gate terminal connected to the terminal from which the first output signal OS1 is output.

The fourth PMOS transistor MP4 may include a source terminal connected to the terminal to which the first power voltage VDD1 is applied, a drain terminal connected to the terminal from which the second output signal OS2 is output, and a gate terminal connected to the terminal to which the operating clock signal OCK is input.

The first PMOS transistor MP1 and the second PMOS transistor MP2 may be connected in parallel between the terminal to which the first power supply voltage VDD1 is applied and the terminal from which the first output signal OS1 is output. The third PMOS transistor MP3 and the fourth PMOS transistor MP4 may be connected in parallel between the terminal to which the first power supply voltage VDD1 is applied and the terminal from which the second output signal OS2 is output.

The first NMOS transistor MN1 may include a drain terminal connected to the terminal from which the second output signal OS2 is output, a source terminal connected to a drain terminal of the second NMOS transistor MN2, and a gate terminal connected to the terminal from which the first output signal OS1 is output.

The second NMOS transistor MN2 may include a drain terminal connected to the source terminal of the first NMOS transistor MN1, a source terminal connected to a first node N1, and a gate terminal connected to the input terminal to which the first input signal IS1 is input.

The third NMOS transistor MN3 may include a drain terminal connected to the terminal from which the first output signal OS1 is output, a source terminal connected to a drain terminal of the fourth NMOS transistor MN4, and a gate terminal connected to the terminal from which the second output signal OS2 is output.

The fourth NMOS transistor MN4 may include a drain terminal connected to the source terminal of the third NMOS transistor MN3, a source terminal connected to the first node N1, and a gate terminal connected to the input terminal to which the second input signal IS2 is input.

The first NMOS transistor MN1 and the second NMOS transistor MN2 may be connected in series between the terminal from which the second output signal OS2 is output and the first node N1. The third NMOS transistor MN3 and the fourth NMOS transistor MN4 may be connected in series between the terminal from which the first output signal OS1 is output and the first node N1.

The fifth NMOS transistor MN5 may include a drain terminal connected to the first node N1, a source terminal connected to a ground voltage GND, and a gate terminal connected to the terminal to which the operating clock signal OCK is input. Herein, for convenience of description, the terms of the ground voltage GND, a ground node GND, and a ground GND may be used interchangeably.

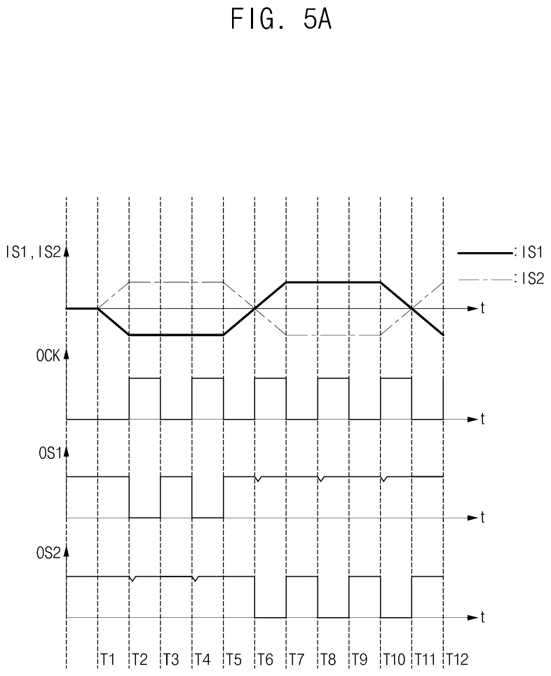

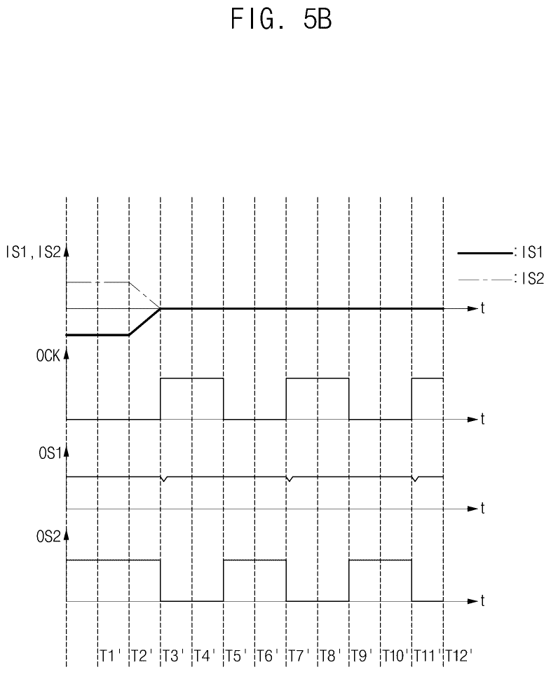

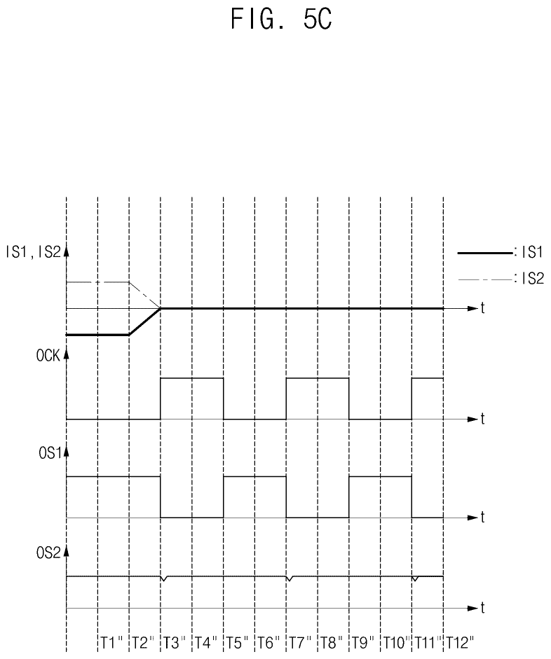

An exemplary operation of the comparator 100a will be described with reference to FIG. 5A.

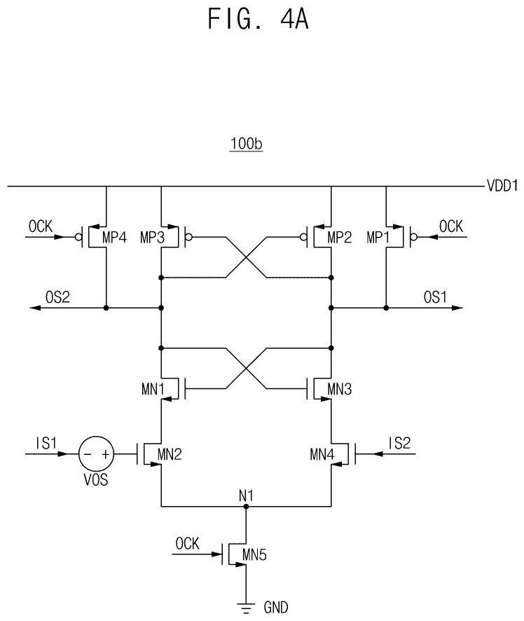

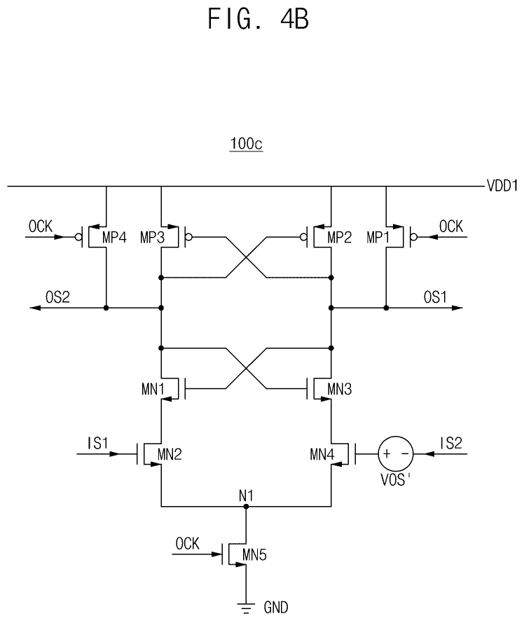

FIGS. 4A and 4B are circuit diagrams for describing an operation of a comparator of FIG. 3 according to example embodiments.

Referring to FIG. 4A, a comparator 100b may further include a voltage source that provides an offset voltage VOS compared to the comparator 100a of FIG. 3. Hereinafter, the descriptions repeated with or overlapping with descriptions of FIG. 3 will be omitted in the interest of brevity.

For example, each of the components included in the comparator 100b may have an offset voltage. Considering all the offset voltages of the components, it may be assumed that there is the offset voltage VOS between the input terminal to which the first input signal IS1 is input and the gate terminal of the second NMOS transistor MN2. In this case, even if the first input signal IS1 and the second input signal IS2 having the same voltage level is applied, the voltage level of the gate terminal of the second NMOS transistor MN2 may be higher than the voltage level of the gate terminal of the fourth NMOS transistor MN4 by the offset voltage VOS.

However, the voltage source is not a component that physically exists in the comparator 100b, and may be a component conceptually added to describe the offset voltages.

An example of an operation of the comparator 100b will be described with reference to FIG. 5B.

Referring to FIG. 4B, a comparator 100c may further include an offset voltage VOS′ compared to the comparator 100a of FIG. 3. Hereinafter, the descriptions repeated with or overlapping with descriptions of FIGS. 3 and 4A will be omitted in the interest of brevity.

For example, each of the components included in the comparator 100c may have an offset voltage. Considering all of the offset voltages of the components, it may be assumed that there is the offset voltage VOS′ between the input terminal to which the second input signal IS2 is input and the gate terminal of the fourth NMOS transistor MN4. In this case, even if the first input signal IS1 and the second input signal IS2 having the same voltage level is applied, the voltage level of the gate terminal of the fourth NMOS transistor MN4 may be higher than the voltage level of the gate terminal of the second NMOS transistor MN2 by the offset voltage VOS′.

An exemplary operation of the comparator 100c will be described with reference to FIG. 5C.

FIG. 5A is a timing diagram for describing an operation of a comparator of FIG. 3 in a normal mode according to example embodiments.

Referring to FIGS. 3 and 5A, the first input signal IS1, the second input signal IS2, the operating clock signal OCK, the first output signal OS1, and the second output signal OS2 are illustrated at a first time point T1, a second time point T2, a third time point T3, a fourth time point T4, a fifth time point T5, a sixth time point T6, a seventh time point T7, an eighth time point T8, a ninth time point T9, a tenth time point T10, an eleventh time point T11, and a twelfth time point T12.

For example, at the first time point T1, the first input signal IS1 and the second input signal IS2 having different voltage levels may be provided or received. For example, when the control signal CTRL changes from a logic low level to a logic high level at the first time point T1, the switch (e.g., the switch 300 in FIG. 2) may be opened, and the first input signal IS1 and the second input signal IS2 having different voltage levels may be received.

For example, from the first time point T1 to the second time point T2, the first input signal IS1 may decrease and the second input signal IS2 may increase. For example, from the second time point T2 to the fifth time point T5, the first input signal IS1 may have a first voltage level and the second input signal IS2 may have a second voltage level higher than the first voltage level. For example, from the fifth time point T5 to the seventh time point T7, the first input signal IS1 may increase and the second input signal IS2 may decrease. For example, from the seventh time point T7 to the tenth time point T10, the first input signal IS1 may have the second voltage level and the second input signal IS2 may have the first voltage level. For example, from the tenth time point T10 to the twelfth time point T12, the first input signal IS1 may decrease and the second input signal IS2 may increase.

For example, the operating clock signal OCK may have a logic low level until the second time point T2. For example, the operating clock signal OCK may have a logic high level from the second time point T2 to the third time point T3. For example, the operating clock signal OCK may change to a logic low level at the third time point T3 and may have a logic low level from the third time point T3 to the fourth time point T4. For example, the operating clock signal OCK may change to a logic high level at the fourth time point T4 and may have a logic high level from the fourth time point T4 to the fifth time point T5.

For example, the operating clock signal OCK may change to a logic low level at the fifth time point T5 and may have a logic low level from the fifth time point T5 to the sixth time point T6. For example, the operating clock signal OCK may change to a logic high level at the sixth time point T6 and may have a logic high level from the sixth time point T6 to the seventh time point T7. For example, the operating clock signal OCK may change to a logic low level at the seventh time point T7 and may have a logic low level from the seventh time point T7 to the eighth time point T8.

For example, the operating clock signal OCK may change to a logic high level at the eighth time point T8 and may have a logic high level from the eighth time point T8 to the ninth time point T9. For example, the operating clock signal OCK may change to a logic low level at the ninth time point T9 and may have a logic low level from the ninth time point T9 to the tenth time point T10. For example, the operating clock signal OCK may change to a logic high level at a tenth time point T10 and may have a logic high level from the tenth time point T10 to the eleventh time point T11. For example, the operating clock signal OCK may change to a logic low level at the eleventh time point T11 and may have a logic low level from the eleventh time point T11 to the twelfth time point T12.

For example, when the operating clock signal OCK has a logic low level, the first PMOS transistor MP1 and the fourth PMOS transistor MP4 may be turned on, and the fifth NMOS transistor MN5 may be turned off. Since the first PMOS transistor MP1 and the fourth PMOS transistor MP4 are turned on, the first output signal OS1 and the second output signal OS2 may have a logic high level.

For example, when the operating clock signal OCK changes from a logic low level to a logic high level, the first PMOS transistor MP1 and the fourth PMOS transistor MP4 may be turned off, and the fifth NMOS transistor MN5 may be turned on.

Assuming that the voltage level of the second input signal IS2 is higher than the voltage level of the first input signal IS1, the amount of the current flowing from the third NMOS transistor MN3 to the fourth NMOS transistor MN4 may be greater than the amount of the current flowing from the first NMOS transistor MN1 to the second NMOS transistor MN2. Therefore, the voltage level of the first output signal OS1 may decrease faster than the voltage level of the second output signal OS2. When the first output signal OS1 has a logic low level, since the terminal from which the first output signal OS1 is output and the gate terminal of the first NMOS transistor MN1 and the gate terminal of the third PMOS transistor MP3 are connected, the first NMOS transistor MN1 may be turned off and the third PMOS transistor MP3 may be turned on.

In this case, since the third PMOS transistor MP3 is turned on, the voltage level of the second output signal OS2, which was decreasing slowly compared to the first output signal OS1, may increase again.

Therefore, when the voltage level of the second input signal IS2 is higher than the voltage level of the first input signal IS1, if the operating clock signal OCK changes from a logic low level to a logic high level, the first output signal OS1 may change to a logic low level and the second output signal OS2 may decrease and then increase.

Assuming that the voltage level of the first input signal IS1 is higher than the voltage level of the second input signal IS2, the amount of the current flowing from the first NMOS transistor MN1 to the second NMOS transistor MN2 may be greater than the amount of the current flowing from the third NMOS transistor MN3 to the fourth NMOS transistor MN4. Therefore, the voltage level of the second output signal OS2 may decrease faster than the voltage level of the first output signal OS1. When the second output signal OS2 has a logic low level, the terminal from which the second output signal OS2 is output, the gate terminal of the third NMOS transistor MN3, and the gate terminal of the second PMOS transistor MP2 are connected, such that the third NMOS transistor MN3 may be turned off and the second PMOS transistor MP2 may be turned on.

In this case, since the second PMOS transistor MP2 is turned on, the voltage level of the first output signal OS1, which was decreasing slowly compared to the second output signal OS2, may increase again.

Therefore, when the voltage level of the first input signal IS1 is higher than the voltage level of the second input signal IS2, if the operating clock signal OCK changes from a logic low level to a logic high level, the second output signal OS2 may change to a logic low level and the first output signal OS1 may decrease and then increase.

For example, from the first time point T1 to the sixth time point T6, the second input signal IS2 may be greater than the first input signal IS1. In this case, at the second time point T2 and the fourth time point T4, at which the operating clock signal OCK changes from a logic low level to a logic high level, the first output signal OS1 changes from a logic high level to a logic low level, and the second output signal OS2 may decrease and then increase again.

For example, from the sixth time point T6 to the eleventh time point T11, the first input signal IS1 may be greater than the second input signal IS2. In this case, at the sixth time point T6, the eighth time point T8, and the tenth time point T10, at which the operating clock signal OCK changes from a logic low level to a logic high level, the second output signal OS2 changes from a logic high level to a logic low level, and the first output signal OS1 may decrease and then increase again.

FIG. 5B is a timing diagram for describing an operation of a comparator of FIG. 4A in an offset calibration mode according to example embodiments.

Referring to FIGS. 4A and 5B, the first input signal IS1, the second input signal IS2, the operating clock signal OCK, the first output signal OS1, and the second output signal OS2 are illustrated at a first time point T1′, a second time point T2′, a third time point T3′, a fourth time point T4′, a fifth time point T5′, a sixth time point T6′, a seventh time point T7′, an eighth time point T8′, a ninth time point T9′, a tenth time point T10′, an eleventh time point T11′, and a twelfth time point T12′.

For example, at the second time point T2′, the first input signal IS1 may increase and the second input signal IS2 may decrease, such that the first input signal IS1 and the second input signal IS2 may have the same voltage level from the third time point T3′. For example, when the control signal CTRL changes from a logic high level to a logic low level at the second time point T2′, the switch (e.g., the switch 300 in FIG. 2) may be closed.

For example, the first input signal IS1 and the second input signal IS2 may have different voltage levels until the third time point T3′, and may have the same voltage level from the third time point T3′.

For example, the operating clock signal OCK may have a logic low level until the third time point T3′. For example, the operating clock signal OCK may have a logic high level from the third time point T3′ to the fifth time point T5′. For example, the operating clock signal OCK may change to a logic low level at the fifth time point T5′ and may have a logic low level from the fifth time point T5′ to the seventh time point T7′. For example, the operating clock signal OCK may change to a logic high level at the seventh time point T7′ and may have a logic high level from the seventh time point T7′ to a ninth time point T9′. For example, the operating clock signal OCK may change to a logic low level at the ninth time point T9′ and may have a logic low level from the ninth time point T9′ to the eleventh time point T11'. For example, the operating clock signal OCK may change to a logic high level at the eleventh time point T11′ and may have a logic high level from the eleventh time point T11′ to the twelfth time point T12′.

For example, the operating clock signal OCK in the normal mode may be the first clock signal (for example, CK1 in FIG. 1), and the operating clock signal OCK in the offset calibrating mode may be the second clock signal (for example, CK2 in FIG. 1). For example, the frequency of the first clock signal CK1 may be a high frequency having a gigahertz (GHZ) unit, and the frequency of the second clock signal CK2 may be a low frequency having a kilohertz (KHZ) or megahertz (MHZ) unit.

For example, when the operating clock signal OCK has a logic low level, the first PMOS transistor MP1 and the fourth PMOS transistor MP4 may be turned on, and the fifth NMOS transistor MN5 may be turned off. Since the first PMOS transistor MP1 and the fourth PMOS transistor MP4 are turned on, the first output signal OS1 and the second output signal OS2 may have a logic high level.

For example, when the operating clock signal OCK changes from a logic low level to a logic high level, the first PMOS transistor MP1 and the fourth PMOS transistor MP4 may be turned off, and the fifth NMOS transistor MN5 may be turned on.

In this case, since the voltage level of the gate terminal of the second NMOS transistor MN2 is higher than the voltage level of the gate terminal of the fourth NMOS transistor MN4 by the offset voltage VOS between the input terminal to which the first input signal IS1 is input and the gate terminal of the second NMOS transistor MN2, the amount of the current flowing from the first NMOS transistor MN1 to the second NMOS transistor MN2 may be greater than the amount of the current flowing from the third NMOS transistor MN3 to the fourth NMOS transistor MN4. Accordingly, the voltage level of the second output signal OS2 may decrease faster than the voltage level of the first output signal OS1. When the second output signal OS2 has a logic low level, since the terminal from which the second output signal OS2 is output and the gate terminal of the third NMOS transistor MN3 and the gate terminal of the second PMOS transistor MP2 are connected, the third NMOS transistor MN3 may be turned off and the second PMOS transistor MP2 may be turned on.

In this case, since the second PMOS transistor MP2 is turned on, the voltage level of the first output signal OS1, which was decreasing slowly compared to the second output signal OS2, may increase again. Since the voltage level of the first output signal OS1 decreases and then increases again, the third PMOS transistor MP3 may continue to be turned off.

For example, when the operating clock signal OCK changes from a logic high level to a logic low level, the first PMOS transistor MP1 and the fourth PMOS transistor MP4 may be turned on, and the fifth NMOS transistor MN5 may be turned off. In this case, since the first PMOS transistor MP1 and the fourth PMOS transistor MP4 are turned on, the first output signal OS1 may have a logic high level, and the second output signal OS2 may change from a logic low level to a logic high level. Accordingly, the second PMOS transistor MP2 and the third PMOS transistor MP3 may be turned off.

For example, at the third time point T3′, the seventh time point T7′, and the eleventh time point T11′, at which the operating clock signal OCK changes from a logic low level to a logic high level, the first output signal OS1 may decrease and then increase again, and the second output signal OS2 may change from a logic high level to a logic low level.

For example, at the fifth time point T5′ and the ninth time point T9′, at which the operating clock signal OCK changes from a logic high level to a logic low level, the first output signal OS1 may have a logic high level, and the second output signal OS2 may change from a logic low level to a logic high level.

For example, when the voltage level of the gate terminal of the second NMOS transistor MN2 is higher than the voltage level of the gate terminal of the fourth NMOS transistor MN4, in the offset calibration mode, the second PMOS transistor MP2 may be repeatedly turned on and off, and the third PMOS transistor MP3 may be turned off. In this case, a voltage level of a threshold voltage of the second PMOS transistor MP2 may decrease, and the second PMOS transistor MP2 may have degraded performance out of a reference performance range. For example, since an absolute value of the threshold voltage of the second PMOS transistor MP2 increases, the difference between the gate-source voltage of the second PMOS transistor MP2 and the threshold voltage may decrease, and the amount of the current of the second PMOS transistor MP2 may decrease.

For example, when the operating clock signal OCK changes from a logic low level to a logic high level, the second output signal OS2 changes from a logic high level to a logic low level, and the first output signal OS1 may slightly decrease from the logic high level and then increase again. In this case, if the amount of the current of the second PMOS transistor MP2 decreases, the increased amount of the first output signal OS1 may gradually decrease. Accordingly, the difference between the first output signal OS1 and the second output signal OS2 gradually decreases, such that the offset calibration operation may be performed.

For example, at the third time point T3′, the operating clock signal OCK may change from a logic low level to a logic high level. As described above, the second output signal OS2 has a logic low level, and the first output signal OS1 may decrease and then increase again as the second PMOS transistor MP2 is turned on. For example, as the second PMOS transistor MP2 is degraded by repeatedly turning on and off, the amount of the current of the second PMOS transistor MP2 may decrease. In this case, since the increased amount of the first output signal OS1 decreases, the difference between the first output signal OS1 and the second output signal OS2 gradually decreases, such that the offset calibration operation may be performed.

FIG. 5C is a timing diagram for describing an operation of a comparator of FIG. 4B in an offset calibration mode according to example embodiments.

Referring to FIGS. 4B and 5C, the first input signal IS1, the second input signal IS2, the operating clock signal OCK, the first output signal OS1, and the second output signal OS2 are illustrated at a first time point T1″, a second time point T2″, a third time point T3″, a fourth time point T4″, a fifth time point T5″, a sixth time point T6″, a seventh time point T7″, an eighth time point T8″, a ninth time point T9″, a tenth time point T10″, an eleventh time point T11″, and a twelfth time point T12″.

For example, at the second time point T2″, the first input signal IS1 may increase and the second input signal IS2 may decrease, such that the first input signal IS1 and the second input signal IS2 may have the same voltage level from the third time point T3″. For example, when the control signal CTRL changes from a logic high level to a logic low level at the second time point T2″, the switch (e.g., the switch 300 in FIG. 2) may be closed.

For example, the first input signal IS1 and the second input signal IS2 may have different voltage levels until the third time point T3″, and may have the same voltage level from the third time point T3″.

For example, the operating clock signal OCK may have a logic low level until the third time point T3″. For example, the operating clock signal OCK may have a logic high level from the third time point T3″ to the fifth time point T5″. For example, the operating clock signal OCK may change to a logic low level at the fifth time point T5″ and may have a logic low level from the fifth time point T5″ to the seventh time point T7″. For example, the operating clock signal OCK may change to a logic high level at the seventh time point T7″ and may have a logic high level from the seventh time point T7″ to the ninth time point T9″. For example, the operating clock signal OCK may change to a logic low level at the ninth time point T9″ and may have a logic low level from the ninth time point T9″ to the eleventh time point T11″. For example, the operating clock signal OCK may change to a logic high level at the eleventh time point T11″ and may have a logic high level from the eleventh time point T11″ to the twelfth time point T12″.

For example, the operating clock signal OCK in the normal mode may be the first clock signal (e.g., CK1 in FIG. 1), and the operating clock signal OCK in the offset calibration mode may be the second clock signal (e.g., CK2 in FIG. 1).

For example, when the operating clock signal OCK has a logic low level, the first PMOS transistor MP1 and the fourth PMOS transistor MP4 may be turned on, and the fifth NMOS transistor MN5 may be turned off. Since the first PMOS transistor MP1 and the fourth PMOS transistor MP4 are turned on, the first output signal OS1 and the second output signal OS2 may have a logic high level.

For example, when the operating clock signal OCK changes from a logic low level to a logic high level, the first PMOS transistor MP1 and the fourth PMOS transistor MP4 may be turned off, and the fifth NMOS transistor MN5 may be turned on.

In this case, since the voltage level of the gate terminal of the fourth NMOS transistor MN4 is higher than the voltage level of the gate terminal of the second NMOS transistor MN2 by the offset voltage VOS′ between the input terminal to which the second input signal IS2 is input and the gate terminal of the fourth NMOS transistor MN4, the amount of the current flowing from the third NMOS transistor MN3 to the fourth NMOS transistor MN4 may be greater than the amount of the current flowing from the first NMOS transistor MN1 to the second NMOS transistor MN2. Accordingly, the voltage level of the first output signal OS1 may decrease faster than the voltage level of the second output signal OS2. When the first output signal OS1 has a logic low level, since the terminal from which the first output signal OS1 is output and the gate terminal of the first NMOS transistor MN1 and the gate terminal of the third PMOS transistor MP3 are connected, the first NMOS transistor MN1 may be turned off and the third PMOS transistor MP3 may be turned on.

In this case, since the third PMOS transistor MP3 is turned on, the voltage level of the second output signal OS2, which was decreasing slowly compared to the first output signal OS1, may increase again. Since the voltage level of the second output signal OS2 decreases and then increases again, the second PMOS transistor MP2 may continue to be turned off.

For example, when the operating clock signal OCK changes from a logic high level to a logic low level, the first PMOS transistor MP1 and the fourth PMOS transistor MP4 may be turned on, and the fifth NMOS transistor MN5 may be turned off. In this case, since the first PMOS transistor MP1 and the fourth PMOS transistor MP4 are turned on, the second output signal OS2 may have a logic high level, and the first output signal OS1 may change from a logic low level to a logic high level. Accordingly, the second PMOS transistor MP2 and the third PMOS transistor MP3 may be turned off.

For example, at the third time point T3″, the seventh time point T7″, and the eleventh time point T11″, at which the operating clock signal OCK changes from a logic low level to a logic high level, the second output signal OS2 may decrease and then increase again, and the first output signal OS1 may change from a logic high level to a logic low level.

For example, at the fifth time point T5″ and the ninth time point T9″, at which the operating clock signal OCK changes from a logic high level to a logic low level, the second output signal OS2 may have a logic high level, and the first output signal OS1 may change from a logic low level to a logic high level.

For example, when the voltage level of the gate terminal of the fourth NMOS transistor MN4 is higher than the voltage level of the gate terminal of the second NMOS transistor MN2, in the offset calibration mode, the third PMOS transistor MP3 may be repeatedly turned on and off, and the second PMOS transistor MP2 may be turned off. In this case, the voltage level of the threshold voltage of the third PMOS transistor MP3 may decrease, and the third PMOS transistor MP3 may have degraded performance out of the reference performance range. In other words, since the absolute value of the threshold voltage of the third PMOS transistor MP3 increases, the difference between the gate-source voltage and the threshold voltage of the third PMOS transistor MP3 may decrease, and the amount of the current of the third PMOS transistor MP3 may decrease.

For example, when the operating clock signal OCK changes from a logic low level to a logic high level, the first output signal OS1 changes from a logic high level to a logic low level, and the second output signal OS2 may slightly decrease from the logic high level and then increase again. In this case, if the amount of the current of the second PMOS transistor MP2 decreases, the increased amount of the second output signal OS2 may gradually decrease. Accordingly, the difference between the first output signal OS1 and the second output signal OS2 gradually decreases, such that the offset calibration operation may be performed.

For example, at the third time point T3″, the operating clock signal OCK may change from a logic low level to a logic high level. As described above, the first output signal OS1 may have a logic low level, and the second output signal OS2 may decrease and then increase again as the third PMOS transistor MP3 is turned on. For example, as the third PMOS transistor MP3 is degraded by repeatedly turning on and off, the amount of the current of the third PMOS transistor MP3 may decrease. In this case, since the increased amount of the second output signal OS2 decreases, the difference between the first output signal OS1 and the second output signal OS2 gradually decreases, such that the offset calibration operation may be performed.

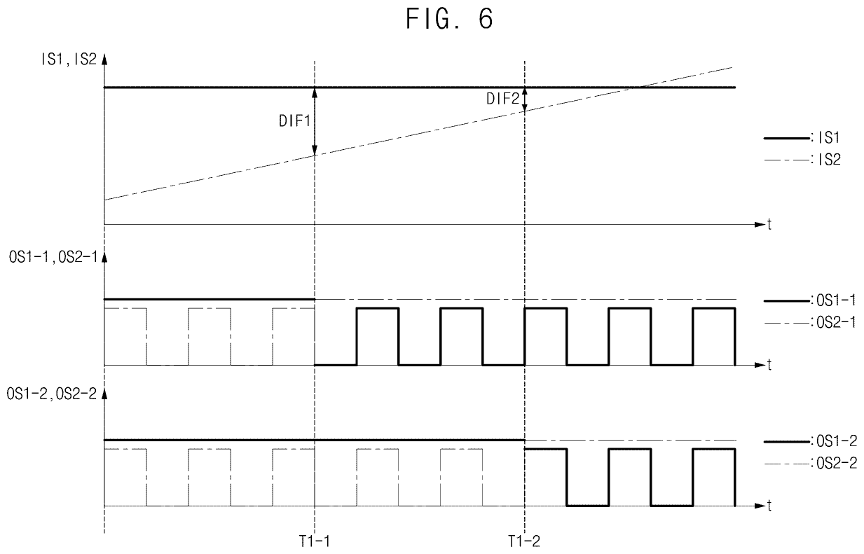

FIG. 6 is a diagram illustrating a simulation result of a comparison circuit according to example embodiments.

Referring to FIG. 6, the first input signal IS1, the second input signal IS2, a first-first output signal OS1-1, a second-first output signal OS2-1, a first-second output signal OS1-2, and a second-second output signal OS2-2 are illustrated at a first-first time point T1-1 and a first-second time point T1-2.

The first-first output signal OS1-1 and the second-first output signal OS2-1 correspond to the first output signal and the second output signal for which the offset calibration operation is not performed, respectively. The first-second output signal OS1-2 and the second-second output signal OS2-2 refer to the first output signal and the second output signal after performing the offset calibration operation by degrading the transistor according to example embodiments, respectively.

As a result of performing a simulation by maintaining the first input signal IS1 constant and increasing the second input signal IS2, the first-first output signal OS1-1 and the second-first output signal OS2-1 may be inverted at the first-first time point T1-1, and the first-second output signal OS1-2 and the second-second output signal OS2-2 may be inverted at the first-second time point T1-2 after the first-first time point T1-1.

The offset before performing the offset calibration operation may mean a first offset DIF1, which is the difference between the first input signal IS1 and the second input signal IS2, at the first-first time point T1-1 where the signal inversion of the first-first output signal OS1-1 and the second-first output signal OS2-1 occurs. The offset after performing the offset calibration operation may mean the second offset DIF2, which is the difference between the first input signal IS1 and the second input signal IS2, at the first-second time point T1-2 where the signal inversion of the first-second output signal OS1-2 and the second-second output signal OS2-2 occurs.

Therefore, the offset of the comparator may be reduced from the first offset DIF1 to the second offset DIF2 by performing the offset calibration operation.

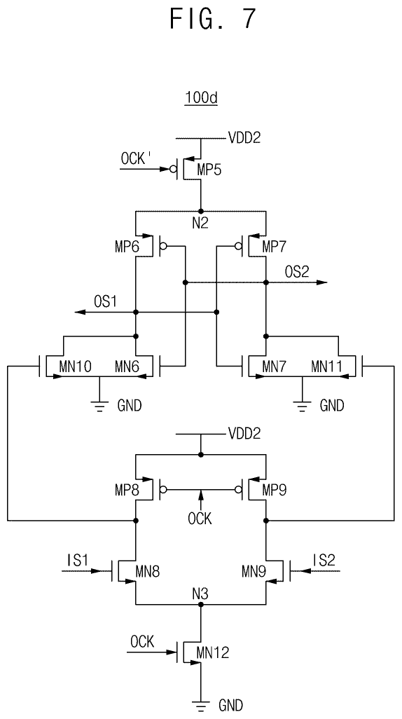

FIG. 7 is a circuit diagram illustrating an example of a comparator included in a comparison circuit of FIG. 1 according to example embodiments.

Referring to FIG. 7, a comparator 100d may include a fifth PMOS transistor MP5, a sixth PMOS transistor MP6, a seventh PMOS transistor MP7, an eighth PMOS transistor MP8, a ninth PMOS transistor MP9, a sixth NMOS transistor MN6, a seventh NMOS transistor MN7, an eighth NMOS transistor MN8, a ninth NMOS transistor MN9, a tenth NMOS transistor MN10, an eleventh NMOS transistor MN11, and a twelfth NMOS transistor MN12.

The fifth PMOS transistor MP5 may include a source terminal connected to a terminal to which a second power supply voltage VDD2 is applied, a drain terminal connected to a second node N2, and a gate terminal connected to a terminal to which an inverted operating clock signal OCK′ is input. In example embodiments, the second power supply voltage VDD2 may be the same as the first power supply voltage VDD1.

The sixth PMOS transistor MP6 may include a source terminal connected to the second node N2, a drain terminal connected to a terminal from which the first output signal OS1 is output, and a gate terminal connected to a terminal from which the second output signal OS2 is output.

The seventh PMOS transistor MP7 may include a source terminal connected to the second node N2, a drain terminal connected to the terminal from which the second output signal OS2 is output, and a gate terminal connected to the terminal from which the first output signal OS1 is output.

The eighth PMOS transistor MP8 may include a source terminal connected to a terminal to which a second power supply voltage VDD2 is applied, a drain terminal connected to the drain terminal of the eighth NMOS transistor MN8 and the gate terminal of the tenth NMOS transistor MN10, and a gate terminal connected to a terminal to which the operating clock signal OCK is input.

The ninth PMOS transistor MP9 may include a source terminal connected to a terminal to which the second power supply voltage VDD2 is applied, a drain terminal connected to a drain terminal of the ninth NMOS transistor MN9 and a gate terminal connected to a gate terminal of the eleventh NMOS transistor MN11, and a gate terminal connected to a terminal to which the operating clock signal OCK is input.

The sixth NMOS transistor MN6 may include a drain terminal connected to the terminal from which the first output signal OS1 is output, a source terminal connected to the ground voltage GND, and a gate terminal connected to the terminal to which a second output signal OS2 is output.

The seventh NMOS transistor MN7 may include a drain terminal connected to the terminal from which a second output signal OS2 is output, a source terminal connected to the ground voltage GND, and a gate terminal connected to the terminal from which the first output signal OS1 is output.

The eighth NMOS transistor MN8 may include a drain terminal connected to the drain terminal of the eighth PMOS transistor MP8 and a gate terminal of the tenth NMOS transistor MN10, a source terminal connected to a third node N3, and a gate terminal connected to the input terminal to which the first input signal IS1 is input.

The ninth NMOS transistor MN9 may include a drain terminal connected to the drain terminal of the ninth PMOS transistor MP9 and the gate terminal of the eleventh NMOS transistor MN11, a source terminal connected to the third node N3, and a gate terminal connected to the input terminal to which the second input signal IS2 is input.

The tenth NMOS transistor MN10 may include a drain terminal connected to the terminal from which the first output signal OS1 is output, a source terminal connected to the ground voltage GND, and a gate terminal connected to the drain terminal of the eighth NMOS transistor MN8 and the drain terminal of the eighth PMOS transistor MP8.

The eleventh NMOS transistor MN11 may include a drain terminal connected to the terminal from which the second output signal OS2 is output, a source terminal connected to the ground voltage GND, and a gate terminal connected to the drain terminal of the ninth NMOS transistor MN9 and the drain terminal of the ninth PMOS transistor MP9.

The twelfth NMOS transistor MN12 may include a drain terminal connected to the third node N3, a source terminal connected to the ground voltage GND, and a gate terminal connected to a terminal to which the operating clock signal OCK is input.

For example, a method of operating the comparator 100d is similar to a method of operating the comparator 100a of FIG. 3, and the timing diagram of the control signal CTRL, the first input signal IS1, the second input signal IS2, the operating clock signal OCK, the first output signal OS1, and the second output signal OS2 may be substantially the same as the timing diagram of FIG. 5A. The inverted operating clock signal OCK′ may mean a signal that inverts the operating clock signal OCK.

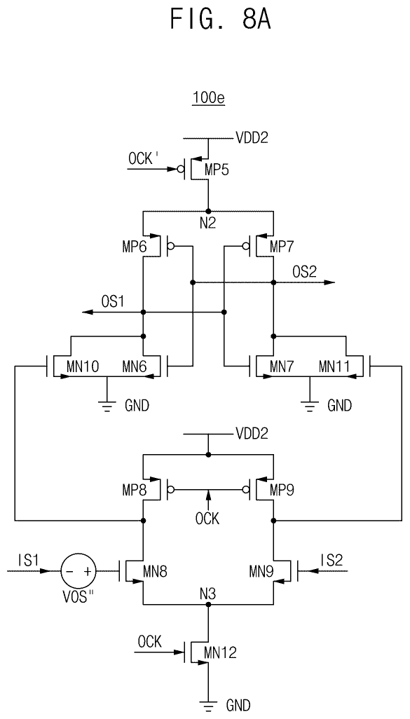

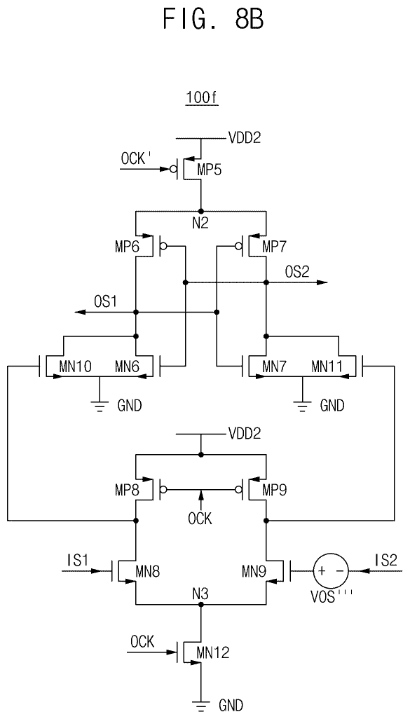

FIGS. 8A and 8B are circuit diagrams for describing an operation of a comparator of FIG. 7 according to example embodiments.

Referring to FIG. 8A, a comparator 100e may further include a voltage source that provides an offset voltage VOS″ compared to the comparator 100d of FIG. 7. Hereinafter, the descriptions repeated with or overlapping with descriptions of FIG. 7 will be omitted in the interest of brevity.

For example, each of the components included in the comparator 100e may have an offset voltage. Considering all the offset voltages of the components, it may be assumed that there is the offset voltage VOS″ between the input terminal to which the first input signal IS1 is input and the gate terminal of the eighth NMOS transistor MN8. In this case, even if the first input signal IS1 and the second input signal IS2 having the same voltage level is applied, the voltage level of the gate terminal of the eighth NMOS transistor MN8 may be higher than the voltage level of the gate terminal of the ninth NMOS transistor MN9 by the offset voltage VOS″.

However, the voltage source is not a component that physically exists in the comparator 100e, and may be a component conceptually added to describe the offset voltages.

Referring to FIG. 8B, a comparator 100f may further include a voltage source that provides an offset voltage VOS′″ compared to the comparator 100d of FIG. 7. Hereinafter, the descriptions repeated with or overlapping with descriptions of FIGS. 7 and 8A will be omitted in the interest of brevity.

For example, each of the components included in the comparator 100f may have an offset voltage. Considering all the offset voltages of the components, it may be assumed that there is the offset voltage VOS′″ between the input terminal to which the second input signal IS2 is input and the gate terminal of the ninth NMOS transistor MN9. In this case, even if the first input signal IS1 and the second input signal IS2 having the same voltage level is applied, the voltage level of the gate terminal of the ninth NMOS transistor MN9 may be higher than the voltage level of the gate terminal of the eighth NMOS transistor MN8 by the offset voltage VOS′″.

For example, a method of operating the comparator 100e of FIG. 8A and the comparator 100f of FIG. 8B may be similar to a method of operating the comparator 100b of FIG. 4A and the comparator 100c of FIG. 4B, respectively. For example, the timing diagrams of the control signal CTRL, the first input signal IS1, the second input signal IS2, the operating clock signal OCK, the first output signal OS1, and the second output signal OS2 in the comparator 100e of FIG. 8A and the comparator 100f of FIG. 8B may be substantially the same as the timing diagrams of FIGS. 5B and 5C, respectively.

For example, in the offset calibration mode, if the voltage level of the gate terminal of the eighth NMOS transistor MN8 is higher than the voltage level of the gate terminal of the ninth NMOS transistor MN9, the sixth PMOS transistor MP6 may be repeatedly turned on and off, and the seventh PMOS transistor MP7 may be turned off. In this case, the sixth PMOS transistor MP6 may have degraded performance out of the reference performance range due to a decrease in the threshold voltage, and the seventh NMOS transistor MP7 may have maintained performance within the reference performance range.

For example, in the offset calibration mode, if the voltage level of the gate terminal of the ninth NMOS transistor MN9 is higher than the voltage level of the gate terminal of the eighth NMOS transistor MN8, the seventh PMOS transistor MP7 may be repeatedly turned on and off, and the sixth PMOS transistor MP6 may be turned off. In this case, the seventh PMOS transistor MP7 may have degraded performance out of the reference performance range due to a decrease in the threshold voltage, and the sixth NMOS transistor MP6 may have maintained performance within the reference performance range.

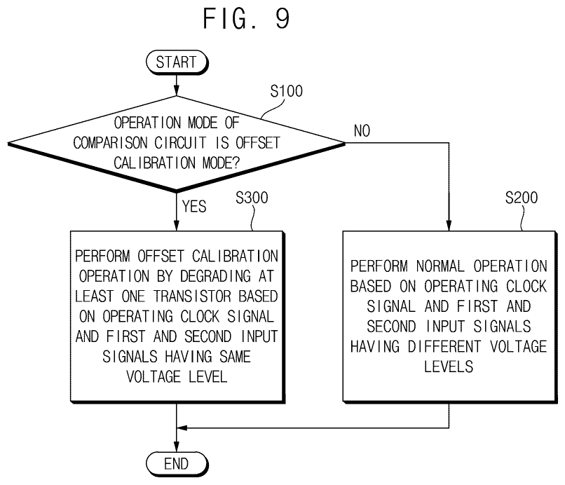

FIG. 9 is a flowchart illustrating a method of operating a comparison circuit according to example embodiments.

Referring to FIG. 9, a method of operating a comparison circuit including at least one transistor is performed by a comparison circuit according to example embodiments (e.g., the comparison circuit 10 of FIG. 1).

As illustrated in FIG. 9, in the method of operating a comparison circuit including at least one transistor according example embodiments, it is determined whether an operation mode of the comparison circuit is an offset compensation mode or a normal mode (operation S100).

When the operation mode of the comparison circuit is the normal mode (operation S100: No), a normal operation is performed based on an operating clock signal and first and second input signals having different voltage levels (operation S200).

When the operation mode of the comparison circuit is the offset calibration mode (operation S100: Yes), an offset calibration operation is performed by degrading the at least one transistor based on the operating clock signal and the first and second input signals having the same voltage level (operation S300).

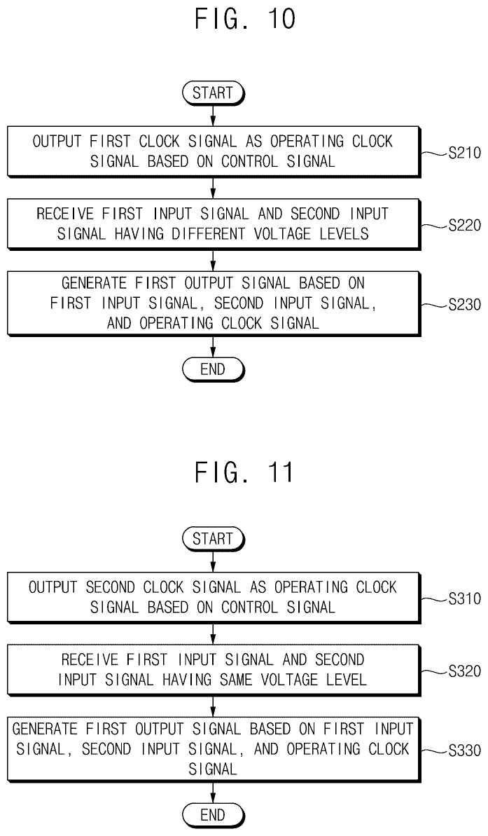

FIG. 10 is a flowchart illustrating an example of performing a normal operation in a method of operating a comparison circuit according to example embodiments.

Referring to FIG. 10, in performing the normal operation (operation S200), the first clock signal is output as the operating clock signal based on a control signal (operation S210).

The first input signal and the second input signal having the different voltage levels are received (operation S220).

A first output signal is generated based on the first input signal, the second input signal, and the operating clock signal (operation S230).

FIG. 11 is a flowchart illustrating an example of performing an offset calibration operation in a method of operating a comparison circuit according to example embodiments.

Referring to FIG. 11, in performing the offset calibration operation (operation S300), a second clock signal is output as the operating clock signal based on the control signal (operation S310).

The first input signal and the second input signal having the same voltage level are received (operation S320).

The first output signal is generated based on the first input signal, the second input signal, and the operating clock signal (operation S330).

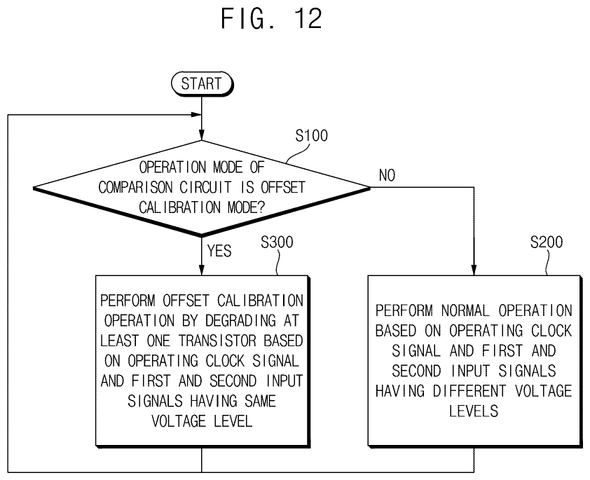

FIG. 12 is a flowchart illustrating a method of operating a comparison circuit according to example embodiments.

Referring to FIG. 12, the method of operating comparison circuit according to example embodiments, operations S100, S200 and S300 may be substantially the same as the operations S100, S200 and S300 in FIG. 9. FIG. 12 illustrates an example where the operations S100, S200 and S300 are repeatedly performed.

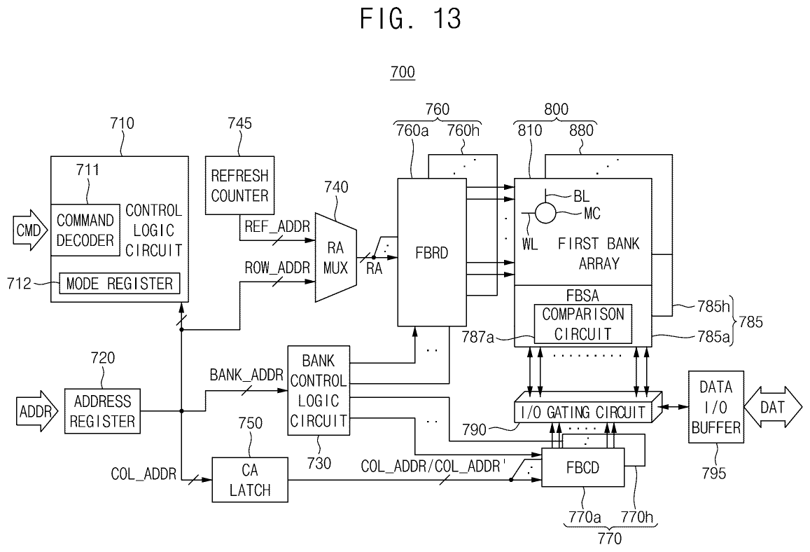

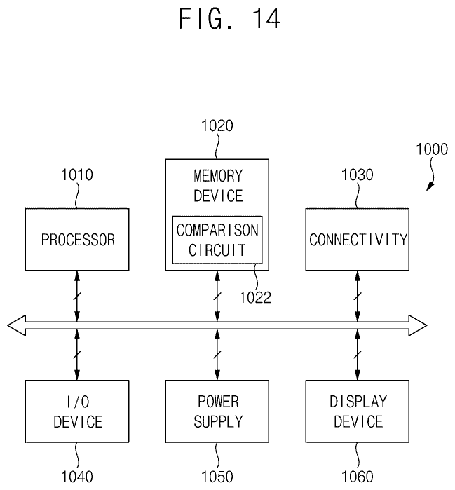

FIG. 13 is a block diagram illustrating a memory device according to example embodiments.

Referring to FIG. 13, a memory device 700 may include a control logic circuit 710, an address register 720, a bank control logic circuit 730, a row address multiplexer 740, a refresh counter 745, a column address latch 750, a row decoder 760, a column decoder 770, a memory cell array 800, a sense amplifier circuit 785, an input/output (I/O) gating circuit 790 and a data I/O buffer 795. For example, the memory device 700 may be one of various volatile memory devices such as a dynamic random access memory (DRAM) device.

The memory cell array 800 may include first to eighth bank arrays 810 to 880 (e.g., first to eighth bank arrays 810, 820, 830, 840, 850, 860, 870 and 880). The row decoder 760 may include first to eighth bank row decoders 760a to 760h connected respectively to the first to eighth bank arrays 810 to 880. The column decoder 770 may include first to eighth bank column decoders 770a to 770h connected respectively to the first to eighth bank arrays 810 to 880. The sense amplifier circuit 785 may include first to eighth bank sense amplifiers 785a to 785h connected respectively to the first to eighth bank arrays 810 to 880. The first to eighth bank sense amplifiers 785a to 785h may each include a comparison circuit the same as the comparison circuit 10 of FIG. 1 or 10a of FIG. 2 previously described. For example, the first bank sense amplifier 785a may include a first comparison circuit 787a. The comparison circuit according to example embodiments may perform offset calibration operation by degrading the transistor included in the comparison circuit.

The first to eighth bank arrays 810 to 880, the first to eighth bank row decoders 760a to 760h, the first to eighth bank column decoders 770a to 770h, and the first to eighth bank sense amplifiers 785a to 785h may form first to eighth banks. Each of the first to eighth bank arrays 810 to 880 may include a plurality of wordlines WL, a plurality of bitlines BL, and a plurality of memory cells MC that are at intersections of the wordlines WL and the bitlines BL.

Although FIG. 13 illustrates the memory device 700 including eight banks (and eight bank arrays, eight row decoders, and so on), the memory device 700 may include any number of banks; for example, one, two, four, eight, sixteen, or thirty two banks, or any number therebetween one and thirty two.

The address register 720 may receive one or more addresses ADDR including a bank address BANK_ADDR, a row address ROW_ADDR, and a column address COL_ADDR from a memory controller that is located outside the memory device 700. The address register 720 may provide the received bank address BANK_ADDR to the bank control logic circuit 730, may provide the received row address ROW_ADDR to the row address multiplexer 740, and may provide the received column address COL_ADDR to the column address latch 750.

The bank control logic circuit 730 may generate bank control signals in response to the bank address BANK_ADDR. One of the first to eighth bank row decoders 760a to 760h corresponding to the bank address BANK_ADDR may be activated in response to the bank control signals, and one of the first to eighth bank column decoders 770a to 770h corresponding to the bank address BANK_ADDR may be activated in response to the bank control signals.

The row address multiplexer 740 may receive the row address ROW_ADDR from the address register 720, and may receive a refresh row address REF_ADDR from the refresh counter 745. The row address multiplexer 740 may selectively output the row address ROW_ADDR or the refresh row address REF_ADDR as a row address RA. The row address RA that is output from the row address multiplexer 740 may be applied to the first to eighth bank row decoders 760a to 760h.

The activated one of the first to eighth bank row decoders 760a to 760h may decode the row address RA that is output from the row address multiplexer 740, and may activate in the corresponding bank array a wordline WL corresponding to the row address RA. For example, the activated bank row decoder may generate a wordline driving voltage, and may apply the wordline driving voltage to the wordline WL corresponding to the row address RA.

The column address latch 750 may receive the column address COL_ADDR from the address register 720, and may temporarily store the received column address COL_ADDR. In some example embodiments, in a burst mode, the column address latch 750 may generate column addresses COL_ADDR′ that increment from the received column address COL_ADDR and provide the column addresses COL_ADDR′ to the first to eighth bank column decoders 770a to 770h. In some example embodiments, the column address latch 750 may apply the temporarily stored column address COL_ADDR to the first to eighth bank column decoders 770a to 770h.

The activated one of the first to eighth bank column decoders 770a to 770h may decode the column address COL_ADDR that is output from the column address latch 750, and may control the I/O gating circuit 790 to output data corresponding to the column address COL_ADDR.

The I/O gating circuit 790 may include circuitry configured to gate input/output data. The I/O gating circuit 790 may further include read data latches configured to store data that is output from the first to eighth bank arrays 810 to 880, and may also include write control devices for writing data to the first to eighth bank arrays 810 to 880.

Data DAT read from one of the first to eighth bank arrays 810 to 880 may be sensed by a sense amplifier connected to the one bank array from which the data DAT is to be read, and may be stored in the read data latches. The data DAT stored in the read data latches may be provided to the memory controller via the data I/O buffer 795. Data DAT to be written in one of the first to eighth bank arrays 810 to 880 may be provided to the I/O gating circuit 790 via the data I/O buffer 795 from the memory controller, and the I/O gating circuit 790 may write the data DAT in the one bank array through the write drivers.

The control logic circuit 710 may control operations of the memory device 700. For example, the control logic circuit 710 may generate control signals for the memory device 700 to perform the write operation and/or the read operation. The control logic circuit 710 may include a command decoder 711 that decodes a command CMD received from the memory controller, and a mode register 712 that sets an operation mode of the memory device 700. In some example embodiments, operations described herein as being performed by the control logic circuit 710 may be performed by processing circuitry. For example, the command decoder 711 may generate the control signals corresponding to the command CMD by decoding a write enable signal, a row address strobe signal, a column address strobe signal, a chip selection signal, etc.

In example embodiments, the offset calibration operation may be performed during a manufacturing process of the memory device 700, and the normal operation may be performed after the manufacturing process of the memory device 700. However, example embodiments are not limited thereto, and the offset calibration operation may be performed after the manufacturing process of the memory device 700.

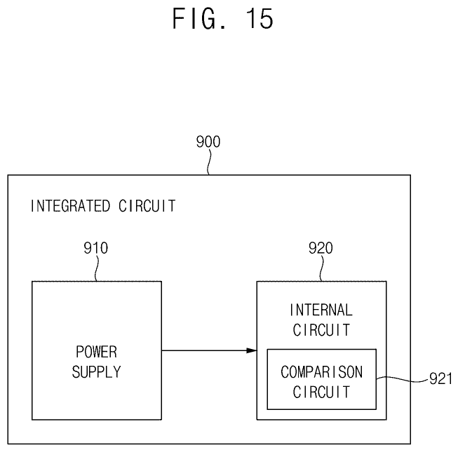

FIG. 14 is a block diagram illustrating an electronic system according to example embodiments.

Referring to FIG. 14, an electronic system 1000 may include a processor 1010, a memory device 1020, a connectivity 1030, an input/output (I/O) device 1040, a power supply 1050 and a display device 1060. The electronic system 1000 may further include a plurality of ports for communicating a video card, a sound card, a memory card, a universal serial bus (USB) device, other electronic devices, etc.

The processor 1010 may control operations of the electronic system 1000. The processor 1010 may execute an operating system and at least one application to provide an internet browser, games, videos, or the like. The connectivity 1030 may communicate with an external device and/or system. The I/O device 1040 may include an input device such as a keyboard, a keypad, a mouse, a touchpad, a touch-screen, a remote controller, etc., and an output device such as a printer, a speaker, etc. The power supply 1050 may provide a power for operations of the electronic system 1000.

The memory device 1020 may store data for the operations of the electronic system 1000 and include a comparison circuit 1022 the same as the comparison circuit 10 of FIG. 1 or 10a of FIG. 2 previously described. The comparison circuit 1022 may perform the offset calibration operation by degrading the transistor included in the comparison circuit 1022.

In example embodiments, the offset calibration operation may be performed during a manufacturing process of the memory device 1020, and the normal operation may be performed after the manufacturing process of the memory device 1020. However, example embodiments are not limited thereto, and the offset calibration operation may be performed after the manufacturing process of the memory device 1020.

FIG. 15 is a block diagram illustrating an integrated circuit according to example embodiments.

Referring to FIG. 15, an integrated circuit 900 includes a power supply device 910 and an internal circuit 920.

For example, the power supply device 910 may generate the output voltage VOUT by performing both the three-level operation and the dual path operation. The internal circuit 920 may perform a specific (or predetermined) operation based on the output voltage (or power supply voltage) VOUT provided from the power supply device 910. For example, the internal circuit 920 may include a comparison circuit 921 the same as the comparison circuit 10 of FIG. 1 or 10a of FIG. 2 previously described. The comparison circuit 921 may perform the offset calibration operation by degrading the transistor.

In example embodiments, the offset calibration operation may be performed during a manufacturing process of the internal circuit 920, and the normal operation may be performed after the manufacturing process of the internal circuit 920. However, example embodiments are not limited thereto, and the offset calibration operation may be performed after the manufacturing process of the internal circuit 920.

The example embodiments may be applied to various electronic devices and systems that include the storage devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

While the inventive concept has been particularly shown and described with reference to embodiments thereof, it will be understood that various changes in form and details may be made therein without departing from the spirit and scope of the present invention as set forth in the following claims.

What is claimed is:

1. A comparison circuit comprising:
a comparator including at least one transistor and configured to generate a first output signal based on a first input signal, a second input signal, and an operating clock signal; and
a multiplexer configured to:
in a normal mode, output a first clock signal as the operating clock signal based on a control signal, and
in an offset calibration mode, output a second clock signal different from the first clock signal as the operating clock signal based on the control signal,
wherein, in the offset calibration mode, the comparison circuit is configured to perform an offset calibration operation by degrading the at least one transistor based on the first and second input signals having the same voltage level and the operating clock signal.

2. The comparison circuit of claim 1, wherein the comparator includes:
a first p-channel metal-oxide semiconductor (PMOS) transistor and a second PMOS transistor connected in parallel between a terminal to which a power supply voltage is applied and a terminal from which the first output signal is output, the first PMOS transistor including a gate terminal connected to a terminal to which the operating clock signal is input, the second PMOS transistor including a gate terminal connected to a terminal from which a second output signal is output;
a third PMOS transistor and a fourth PMOS transistor connected in parallel between the terminal to which the power supply voltage is applied and the terminal from which the second output signal is output, the third PMOS transistor including a gate terminal connected to the terminal from which the first output signal is output, the fourth PMOS transistor including a gate terminal connected to the terminal to which the operating clock signal is input;
a first n-channel metal-oxide semiconductor (NMOS) transistor and a second NMOS transistor connected in series between the terminal from which the second output signal is output and a first node, the first NMOS transistor including a gate terminal connected to the terminal from which the first output signal is output, the second NMOS transistor including a gate terminal connected to a terminal to which the first input signal is input;
a third NMOS transistor and a fourth NMOS transistor connected in series between the terminal from which the first output signal is output and the first node, the third NMOS transistor including a gate terminal connected to the terminal from which the second output signal is output, the fourth NMOS transistor including a gate terminal connected to a terminal to which the second input signal is input; and
a fifth NMOS transistor connected between the first node and a ground node, and including a gate terminal connected to the terminal to which the operating clock signal is input.

3. The comparison circuit of claim 2, wherein, in the normal mode, each gate terminal of the first PMOS transistor, the fourth PMOS transistor, and the fifth NMOS transistor is configured to receive the first clock signal having a first frequency.

4. The comparison circuit of claim 3, wherein, in the offset calibration mode, each gate terminal of the first PMOS transistor, the fourth PMOS transistor, and the fifth NMOS transistor is configured to receive the second clock signal having a second frequency lower than the first frequency.

5. The comparison circuit of claim 4, wherein, in the offset calibration mode, one of the second PMOS transistor and the third PMOS transistor is configured to be repeatedly turned on and off, and the other of the second PMOS transistor and the third PMOS transistor is configured to be turned off.

6. The comparison circuit of claim 4, wherein, in the offset calibration mode:
when a voltage level of the gate terminal of the second NMOS transistor is higher than a voltage level of the gate terminal of the fourth NMOS transistor, the third PMOS transistor is configured to be turned off and the second PMOS transistor is configured to be repeatedly turned on and off, and
when the voltage level of the gate terminal of the fourth NMOS transistor is higher than the voltage level of the gate terminal of the second NMOS transistor, the third PMOS transistor is configured to be repeatedly turned on and off and the second PMOS transistor is configured to be turned off.

7. The comparison circuit of claim 6, wherein, in the offset calibration mode, when the voltage level of the gate terminal of the second NMOS transistor is higher than the voltage of the gate terminal of the fourth NMOS transistor, the second PMOS transistor is configured to have degraded performance out of a reference performance range, and the third PMOS transistor is configured to have maintained performance within the reference performance range.

8. The comparison circuit of claim 7, wherein, in the offset calibration mode, when the voltage level of the gate terminal of the second NMOS transistor is higher than the voltage level of the gate terminal of the fourth NMOS transistor, a voltage level of a threshold voltage of the second PMOS transistor decreases.

9. The comparison circuit of claim 6, wherein, in the offset calibration mode, when the voltage level of the gate terminal of the fourth NMOS transistor is higher than the voltage level of the gate terminal of the second NMOS transistor, the third PMOS transistor is configured to have degraded performance out of a reference performance range, and the second PMOS transistor is configured to have maintained performance within the reference performance range.

10. The comparison circuit of claim 1, wherein the comparator includes:
a fifth PMOS transistor connected between a terminal to which a power supply voltage is applied and a second node, and including a gate terminal connected to a terminal to which an inverted operating clock signal is input, which is an inverted signal of the operating clock signal;
a sixth PMOS transistor and a sixth NMOS transistor connected in series between the second node and a ground node, the sixth PMOS transistor including a drain terminal connected to a terminal from which the first output signal is output and a gate terminal connected to a terminal from which a second output signal is output, the sixth NMOS transistor including a drain terminal connected to the terminal from which the first output signal is output and a gate terminal connected to the terminal from which the second output signal is output;
a seventh PMOS transistor and a seventh NMOS transistor connected in series between the second node and the ground node, the seventh PMOS transistor including a drain terminal connected to the terminal from which the second output signal is output and a gate terminal connected to the terminal from which the first output signal is output, the seventh NMOS transistor including a drain terminal connected to the terminal from which the second output signal is output and a gate terminal connected to the terminal from which the first output signal is output;
an eighth PMOS transistor and an eighth NMOS transistor connected in series between a terminal to which the power supply voltage is applied and a third node, the eighth PMOS transistor including a gate terminal connected to a terminal to which the operating clock signal is input, and the eighth NMOS transistor including a gate terminal connected to a terminal to which the first input signal is input;
a ninth PMOS transistor and a ninth NMOS transistor connected in series between the terminal to which the power supply voltage is applied and the third node, the ninth PMOS transistor including a gate terminal connected to the terminal to which the operating clock signal is input, and the ninth NMOS transistor including a gate terminal connected to a terminal to which the second input signal is input;
a tenth NMOS transistor including a drain terminal connected to the drain terminal of the sixth NMOS transistor and a gate terminal connected to a drain terminal of the eighth PMOS transistor;
an eleventh NMOS transistor including a drain terminal connected to the drain terminal of the seventh NMOS transistor and a gate terminal connected to a drain terminal of the ninth PMOS transistor; and
a twelfth NMOS transistor connected between the third node and the ground node, and including a gate terminal connected to the terminal to which the operating clock signal is input.

11. The comparison circuit of claim 10, wherein, in the offset calibration mode, one of the sixth PMOS transistor and the seventh PMOS transistor is configured to be repeatedly turned on and off, and the other of the sixth PMOS transistor and the seventh PMOS transistor is configured to be turned off.

12. The comparison circuit of claim 11, wherein, in the offset calibration mode, when a voltage level of the gate terminal of the eighth NMOS transistor is higher than a voltage level of the gate terminal of the ninth NMOS transistor, a voltage level of a threshold voltage of the sixth PMOS transistor decreases.

13. The comparison circuit of claim 11, wherein, in the offset calibration mode, when a voltage level of the gate terminal of the ninth NMOS transistor is higher than a voltage level of the gate terminal of the eighth NMOS transistor, the seventh PMOS transistor is configured to have degraded performance out of a reference performance range, and the sixth PMOS transistor is configured to have maintained performance within the reference performance range.

14. The comparison circuit of claim 10, wherein, in the offset calibration mode:
when a voltage level of the gate terminal of the eighth NMOS transistor is higher than a voltage level of the gate terminal of the ninth NMOS transistor, the sixth PMOS transistor is configured to be repeatedly turned on and off, and the seventh PMOS transistor is configured to be turned off, and
when the voltage level of the gate terminal of the ninth NMOS transistor is higher than the voltage level of the gate terminal of the eighth NMOS transistor, the sixth PMOS transistor is configured to be turned off, and the seventh PMOS transistor is configured to be repeatedly turned on and off.

15. The comparison circuit of claim 1, wherein the comparison circuit is configured to:
perform the offset calibration operation in the offset calibration mode during a manufacturing process of the comparison circuit, and
perform a normal operation in the normal mode after the manufacturing process of the comparison circuit.

16. The comparison circuit of claim 1, further comprising:
a switch connected between an input terminal to which the first input signal is input and an input terminal to which the second input signal is input, the switch configured to be opened in the normal mode and to be closed in the offset calibration mode based on the control signal.

17. A method of operating a comparison circuit including at least one transistor, the method comprising:
determining whether an operation mode of the comparison circuit is an offset calibration mode or a normal mode;
when the operation mode of the comparison circuit is the offset calibration mode, performing an offset calibration operation by degrading the at least one transistor based on first and second input signals having the same voltage level and an operating clock signal; and
when the operation mode of the comparison circuit is the normal mode, performing a normal operation based on the first and second input signals having different voltage levels and the operating clock signal.

18. The method of claim 17, wherein the performing of the normal operation includes:
outputting a first clock signal as the operating clock signal based on a control signal;
receiving the first input signal and the second input signal having the different voltage levels; and
generating a first output signal based on the first input signal, the second input signal, and the first clock signal.

19. The method of claim 17, wherein the performing of the offset calibration operation includes:
outputting a second clock signal as the operating clock signal based on a control signal;
receiving the first input signal and the second input signal having the same voltage level; and
generating a first output signal based on the first input signal, the second input signal, and the second clock signal.

20. A comparison circuit comprising:
a comparator including at least one transistor and configured to generate a first output signal based on a first input signal, a second input signal, and an operating clock signal; and
a multiplexer configured to:
in a normal mode, output a first clock signal as the operating clock signal based on a control signal, and
in an offset calibration mode, output a second clock signal different from the first clock signal as the operating clock signal based on the control signal,
wherein, in the offset calibration mode, the first input signal and the second input signal have the same voltage level,
wherein the comparator includes:
a first p-channel metal-oxide semiconductor (PMOS) transistor and a second PMOS transistor connected in parallel between a terminal to which a power supply voltage is applied and a terminal from which the first output signal is output, the first PMOS transistor including a gate terminal connected to a terminal to which the operating clock signal is input, the second PMOS transistor including a gate terminal connected to a terminal from which a second output signal is output;
a third PMOS transistor and a fourth PMOS transistor connected in parallel between the terminal to which the power supply voltage is applied and the terminal from which the second output signal is output, the third PMOS transistor including a gate terminal connected to the terminal from which the first output signal is output, the fourth PMOS transistor including a gate terminal connected to the terminal to which the operating clock signal is input;
a first n-channel metal-oxide semiconductor (NMOS) transistor and a second NMOS transistor connected in series between the terminal from which the second output signal is output and a first node, the first NMOS transistor including a gate terminal connected to the terminal from which the first output signal is output, the second NMOS transistor including a gate terminal connected to a terminal to which the first input signal is input;
a third NMOS transistor and a fourth NMOS transistor connected in series between the terminal from which the first output signal is output and the first node, the third NMOS transistor including a gate terminal connected to the terminal from which the second output signal is output, the fourth NMOS transistor including a gate terminal connected to a terminal to which the second input signal is input; and
a fifth NMOS transistor connected between the first node and a ground node, and including a gate terminal connected to the terminal to which the operating clock signal is input,
wherein, in the offset calibration mode, when a voltage level of the gate terminal of the second NMOS transistor is higher than a voltage level of the gate terminal of the fourth NMOS transistor, the comparison circuit is configured such that the second PMOS transistor has a threshold voltage being decreased, and
wherein the comparison circuit is configured to:
perform the offset calibration operation in the offset calibration mode during a manufacturing process of the comparison circuit, and
perform a normal operation in the normal mode after the manufacturing process of the comparison circuit.
